(19) United States
(12) Patent Application Publication
(10) Pub. No.: US 2015/0070774 A1
(43) Pub. Date: Mar. 12, 2015

(54) WAVELENGTH-CONTROLLED DIODE LASER MODULE WITH EXTERNAL RESONATOR

(71) Applicant: SHOWA OPTRONICS CO., LTD., Tokyo (JP)

(72) Inventors: Minoru Kadoya, Tokyo (JP); Atsushi Masui, Yokohama-shi (JP)

(73) Assignee: SHOWA OPTRONICS CO., LTD., Tokyo (JP)

(21) Appl. No.: 14/191,351

(22) Filed: Feb. 26, 2014

(30) Foreign Application Priority Data
Sep. 11, 2013 (JP) 2013-188100

(51) Int. Cl. H01S 5/00; G02B 26/00

(52) U.S. Cl. CPC H01S 5/0078; G02B 26/002
USPC 359/634

(57) ABSTRACT

A diode laser module includes a laser diode (1), an anamorphic prism pair (5) consisting of a pair of prisms (3, 4) having mutually different apex angles and/or made of material having mutually different refractive indices, and a partial reflective mirror (6; 16) disposed on a side of the anamorphic prism pair away from the laser diode and having a planar or spherical surface facing the anamorphic prism pair and coated with partial reflective coating (6a; 16a). The wavelength of the laser output can be changed by adjusting the position of the partial reflective mirror.

### TECHNICAL FIELD

The present invention relates to a diode laser module provided with an external resonator including an anamorphic prism pair for controlling the wavelength of the output laser light.

### PRIOR ART

Laser diodes that emit laser light by injection of electric current by using semiconductor as a gain medium are known to demonstrate wide variations in the central wavelength of the emitted laser light. The mass produced, commercially available laser diodes are typically given with a tolerance of ±3 nm to ±5 nm in the central wavelength. The central wavelength of a laser diode is also affected by the input current and the temperature.

There may be applications where the variations and changes in the central wavelength of the laser diode are not a problem. However, in the applications for analysis and measurement, even small variations and changes in the central wavelength are not acceptable in some cases.

By taking advantage of the fact that the central wavelength of a laser diode depends on temperature, it has been proposed to control the central wavelength of a laser diode by adjusting the temperature of the laser diode. For instance, the temperature coefficient of the central wavelength is typically about +0.3 nm/K in the case of an AlGaAs laser diode with a wavelength of approximately 0.8 μm, and about +0.1 nm/K in the case of an InGaN laser diode with a wavelength of approximately 0.4 μm. It is therefore possible to shift the central wavelength to shorter wavelength side by reducing the temperature and to longer wavelength side by increasing the temperature, while taking into account the desired amount of wavelength shift and the temperature coefficient of the laser diode.

Another proposal is based on the use of a volume holographic grating (VHG) for controlling the wavelength of a laser diode. See U.S. Pat. No. 7,636,376, for instance. The volume holographic grating is also known as a volume Bragg grating (VBG). The volume holographic grating consists of a glass element having a periodic change in the refractive index thereof along a prescribed direction, and has the property to reflect light of a particular incident angle such that the reflected light has a particular wavelength. According to the invention disclosed in U.S. Pat. No. 7,636,376, output light of a laser diode is directed vertically onto volume holographic grating, and the light reflected thereby is coupled to the laser diode so that the operating wavelength of the laser diode is controlled to a prescribed wavelength determined by the property of the volume holographic grating.

Another example of a laser module using an optical diffraction grating is disclosed in U.S. Pat. No. 5,594,744. In this example, the use is made of the property of the diffraction grating which propagates the laser light in wavelength dependent directions. In particular, the diffracted light which has propagated in a certain direction is reflected back to the laser diode by adjusting the angle of a reflective mirror so as to couple the diffracted light of a prescribed wavelength to the laser diode.

An example of a laser module using prisms is disclosed in “Tunable Laser Applications” by Frank J. Duarte, 2nd edition, CRC Press, 2008, Chapter 5. This prior art is similar to that disclosed in U.S. Pat. No. 5,594,744 in that the wavelength selection is achieved by the use of an optical diffraction grating. However, to further improve the wavelength selectivity, the cross sectional shape of the beam of laser light is elongated in a prescribed direction by using a plurality of prisms before being made incident to the optical diffraction grating.

“Tunable Laser Applications” also discloses an example where an Etalon device is utilized. This prior art is similar to that disclosed in U.S. Pat. No. 5,594,744 in that the wavelength selection is achieved by the use of an optical diffraction grating. However, to further improve the wavelength selectivity, an Etalon device is placed in the optical path between the laser diode and the optical diffraction grating.

Although not an application of a laser diode, U.S. Pat. No. 4,462,103 discloses an optically pumped semiconductor platelet laser. A single prism is placed in a laser resonator formed between a semiconductor platelet serving as a gain medium and an output mirror so that the narrowing of the bandwidth of the optical spectrum and tuning of the wavelength may be accomplished by the prism.

In the cases of the prior art where the wavelength is controlled via the temperature of the laser diode, the temperature can be dropped only insofar as there is no moisture condensation, and the service life of the laser diode may be adversely affected by increasing the temperature of the laser diode. Furthermore, a significant amount of electric power is required for the temperature control, and the power consumed by the temperature control may even exceed the power supplied to the laser diode.

In the prior art that uses VHG as that disclosed in U.S. Pat. No. 7,636,376, the prior art that uses optical diffraction grating as that disclosed in U.S. Pat. No. 5,594,744, or the prior art using both an Etalon device and a prism as that disclosed in “Tunable Laser Applications”, the laser operates under a single longitudinal mode or a multi longitudinal mode with a small number of longitudinal modes, so that mode hops may occur when the input current of the laser diode is varied or when the temperature of the pressure of the diode laser module changes, with the result that the level of the output laser may unexpectedly change.

In the prior art where an optical diffraction grating is used or the prior art where wavelength selection is made by a single prism in an optically pumped semiconductor platelet laser, the optical path is required to be greatly bent for wavelength selection, and the size of the diode laser module becomes unacceptably great.

### BRIEF SUMMARY OF THE INVENTION

In view of such problems of the prior art, a primary object of the present invention is to provide a diode laser module which allows the central frequency to be favorably controlled and the variations in the central frequency to be minimized.

A second object of the present invention is to provide a diode laser module which can adjust the central frequency and can still be constructed as a highly compact unit.

A third object of the present invention is to provide a diode laser module which can avoid unexpected changes in the output laser power caused by mode hopping.

According to the present invention, such objects can be accomplished by providing a diode laser module, comprising: a laser diode having a laser light emitting end coated with an anti reflective coating; a collimator lens for collimating laser light emitted from the laser diode; an anamorphic prism pair consisting of a pair of prisms having mutually different apex angles and/or made of materials having mutually different refractive indices for shaping a beam of the laser light collimated by the collimator lens into a substantially circular cross section; a partial reflective mirror disposed on a side of the anamorphic prism pair away from the laser diode for reflecting a part of laser light transmitted by the anamorphic prism pair back to the laser diode via the anamorphic prism pair and the collimator lens to couple to an active region of the laser diode; and a mechanism for adjusting a position of the partial reflective mirror

Thereby, the wavelength of the output laser light can be adjusted by changing the position of the partial reflective mirror.

According to a preferred embodiment of the present invention, laser light incident to the anamorphic prism pair and laser light emerging from the anamorphic prism pair are substantially parallel to each other.

Thereby, the diode laser module can be constructed as a highly compact unit, in particular when the lateral offset between the incident laser light and the emerging laser light of the anamorphic prism pair is small.

Preferably, the partial reflective mirror comprises a glass plate having a first surface facing the anamorphic prism pair and coated with a partial reflective coating and a second surface facing away from the anamorphic prism pair and coated with an anti reflective coating.

The first and second surfaces may be defined by mutually parallel planes. In this case, the mechanism for adjusting a position of the partial reflective mirror comprises a pivoting mechanism configured to change an angular position of the partial reflective mirror. Alternatively, it is possible that the first surface is defined by a spherical surface while the second surface is defined by a plane. In this case, the mechanism for adjusting a position of the partial reflective mirror comprises a sliding mechanism configured to change the position of the partial reflective mirror in a direction perpendicular to laser light incident thereto.

According to the diode laser module of the present invention, the wavelength of the output laser light can be adjusted in a highly simple manner and at a high efficiency. Furthermore, even when the atmospheric pressure changes significantly, when the input current widely changes and/or when the temperature of the laser diode is changed significantly, the central frequency of the output laser light can be maintained at a relatively constant value. Also, because the diode laser operates under a multi longitudinal mode including a large number of longitudinal modes, sudden changes in the laser output caused by mode hopping can be avoided. Because the output laser power is caused to increase monotonically in relation to the input current, automatic power control (APC) can be performed in a highly stable manner.

According to the present invention, the diode laser module includes an anamorphic prism pair consisting of a pair of prisms having mutually different apex angles and/or made of material having mutually different refractive indices, and a partial reflective mirror disposed on a side of the anamorphic prism pair away from the laser diode and having a planar or spherical surface facing the anamorphic prism pair and coated with partial reflective coating.

As the anamorphic prism pair consists of a pair of prisms having different wavelength dispersion properties, and the wavelength dispersion properties of the two prisms cancel each other to a certain extent, the anamorphic prism pair is given with an appropriate and favorable wavelength dispersion property.

The diode laser module provided by the present invention is particularly useful in applications such as analysis and measurement where the precision in the central wavelength is necessary. In particular, the diode laser module of the present invention can be constructed as a highly compact and energy efficient unit.

### BRIEF DESCRIPTION OF THE DRAWINGS

FIG. 1 is a schematic diagram showing the structure of a first embodiment of the diode laser module according to the present invention;

FIG. 2 is a schematic diagram illustrating the working principle of the first embodiment shown in FIG. 1;

FIG. 3 is a view similar to FIG. 1 showing a second embodiment of the present invention; and

FIG. 4 is a schematic diagram illustrating the working principle of the second embodiment shown in FIG. 3.

### DETAILED DESCRIPTION OF THE PREFERRED EMBODIMENTS

### First Embodiment

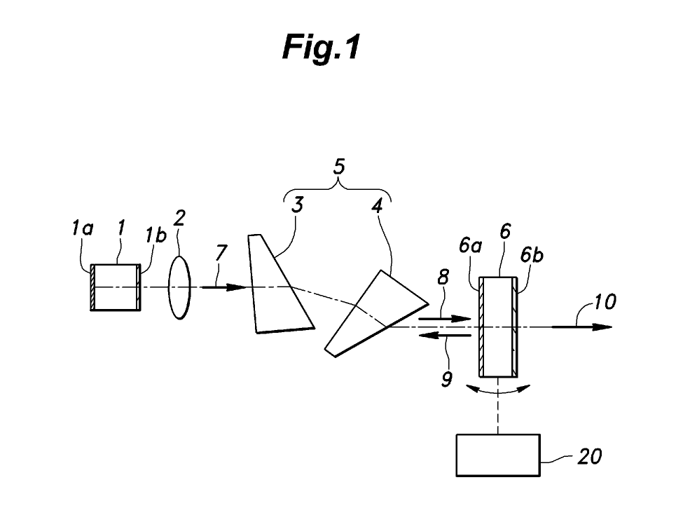

FIG. 1 shows the optical arrangement of a diode laser module given as a first embodiment of the present invention. This diode laser module includes a laser diode 1 which consists of an InGaN diode having a gain peak wavelength of 405 nm. A first end 1a of an active layer of the laser diode 1 is provided with a high reflectance coating having a reflectance of 95% or higher for the wavelength of 405 nm, and a second end 1b thereof is provided with an anti reflective coating having a reflectance of 1% or less for the wavelength of 405 nm. When adequate input current is received, this laser diode 1 is able to emit laser light by itself without the aid of external optical devices.

A collimator lens 2 consisting of an aspherical lens is placed opposite to the second end 1b of the laser diode 1 with the anti reflective coating to collimate the laser light emitted from the laser diode 1. The cross sectional shape of the collimated laser light 7 is elliptic in shape, and the major axis/mirror axis ratio of the ellipse is approximately 2.

The collimated laser light 7 is made incident to an anamorphic prism pair 5 including a first prism 3 and a second prism 4. The anamorphic prism pair 5 reduces the beam of the laser light 7 in the major axis direction by one half so that the laser light 8 that has passed through the anamorphic prism pair 5 is shaped into a laser beam having a substantially circular cross section. The optical axis of the laser light 8 that has passed through the anamorphic prism pair 5 is parallel to the optical axis of the laser light 7 that is incident to the anamorphic prism pair 5 with a lateral offset of about 2 mm.

The laser light 8 that has passed through the anamorphic prism pair 5 is made incident to a partial reflective mirror 6 essentially consisting of a glass plate. The side of the partial reflective mirror 6 facing the anamorphic prism pair 5 is coated with a partial reflective multi layer dielectric coating 6a having a reflectance of about 10% for a wavelength range of the laser light 8. The other side of the partial reflective mirror 6 facing away from the anamorphic prism pair 5 is coated with an anti reflective multi layer dielectric coating 6b. The surfaces on which the partial reflective multi layer dielectric coating 6a and the anti reflection multi layer dielectric coating 6b are formed are defined by planes that are parallel to each other. 10% of the laser light 8 incident to the partial reflective mirror 6 is reflected by the partial reflective mirror 6 (as laser light 9), and the remainder of the laser light 8 is transmitted by the partial reflective mirror 6 (as laser light 10).

The partial reflective mirror 6 can be angularly adjusted around an axial line extending perpendicular to the laser lights 7 and 8 or, more specifically, in a direction perpendicular to the paper of FIG. 1, as indicated by an arcuate arrow. By appropriately adjusting the angle of the partial reflective mirror 6 by using a suitable pivoting mechanism 20, a desired wavelength component of the laser light 9 that is reflected by the partial reflective multi layer dielectric coating 6a of the partial reflective mirror 6 is allowed to propagate back to the light emitting region of the laser diode 1 via the anamorphic prism pair 5 and the collimator lens 2.

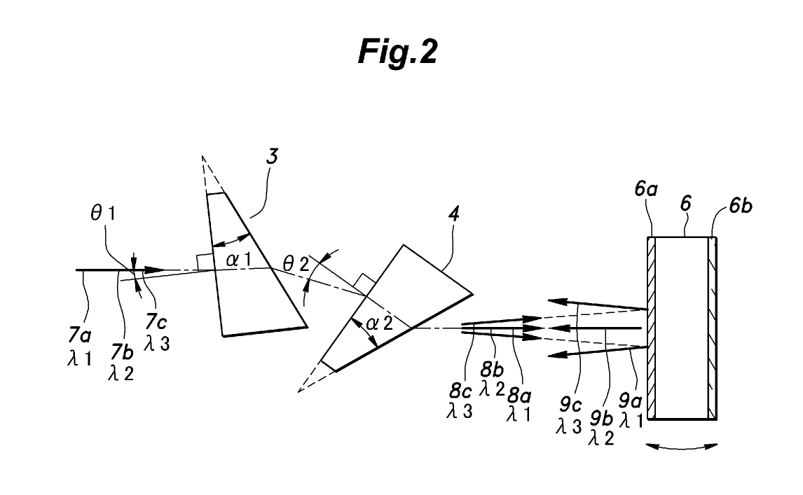

The details of the anamorphic prism pair 5 are described in the following with reference to FIG. 2. The first prism 3 is made of glass material marketed under the trade name of S-TIH10 (SF10 equivalent) by Ohara Inc. in Sagamihara-shi, Kanagawa-ken, Japan, and has an apex angle α1 of 20 degrees. The second prism 4 is made of the same glass material, and has an apex angle α2 of 15 degrees. The surfaces of these prisms 3 and 4 through which the laser light 7 passes are coated with an anti reflective coating (not shown in the drawings).

The face of the first prism 3 facing the collimator lens 2 is tilted by 6 degrees with respect to the optical axis of the incident laser light 7 so that the incident angle θ1 of the laser light 7 is 6 degrees. The refraction angle when the laser light propagates from the glass to the air is 44.8 degrees. The beam reduction ratio by the first prism 3 is 0.78.

The face of the second prism 4 facing the first prism 3 is tilted by 43.9 degrees with respect to the optical axis of the incident laser light 7 so that the incident angle θ2 of the laser light to the second prism 4 is 25.1 degrees. The refraction angle when the laser light propagates from the glass to the air is 58.9 degrees. The beam reduction ratio by the second prism 4 is 0.63.

Thus, as the laser light 7 passes through the anamorphic prism pair 5 consisting of the first prism 3 and the second prism 4, the cross section of the beam of the laser light which was originally elliptic is reduced by about one half in the major axis direction of the ellipse.

The working principle of the wavelength selection in the illustrated embodiment is described in the following with reference to FIG. 2. The laser light 8 that leaves the anamorphic prism pair 5 is in parallel with the laser light 7 incident to the anamorphic prism pair 5. Therefore, the anamorphic prism pair 5 causes substantially no deflection of the transmitted laser light. However, to be more exact, different wavelength components of the laser light deflect at different angles as the laser light passes through the anamorphic prism pair 5. More specifically, the deflection angle of the laser light has a wavelength dependency of 127 μrad/nm. In this anamorphic prism pair 5, the first prism 3 alone provides a wavelength dependency of 248 μrad/nm, and the second prism 4 alone provides a wavelength dependency of −266 μrad/nm, but as the change in the angle of emergence of the second prism 4 is magnified by the factor 0.58 with respect to the change in the incident angle θ2 of the second prism 4, the overall wavelength dependency is given by 127 μrad/nm.

Suppose that the desired wavelength is λ2, and that λ1 signifies a wavelength shorter than λ2, and λ3 signifies a wavelength longer than λ2. Before wavelength selection is made, the laser light components 7a, 7b and 7c having the wavelengths of λ1, λ2 and λ3, respectively, propagate along the same optical axis when the laser light is emitted from the laser diode 1 and collimated by the collimator lens 2. However, when the laser light passes through the anamorphic prism pair 5 having a wavelength dependency in the deflection angle of the laser light, the different components of the laser light are separated from one another, and propagate in different directions as laser light components 8a, 8b and 8c.

In FIG. 2, the laser light component 8b is made incident to the partial reflective mirror 6 perpendicularly thereto (zero incident angle). A part of the laser light component 8b is reflected by the partial reflective coating 6a as a laser light component 9b, and after following the preceding light path, is coupled to the active region of the laser diode 1. The remaining light components 8a and 8c are also reflected by the partial reflective coating 6a, but owing to the non-zero incident angles thereof, the reflected laser light components 9a and 9c follow similar paths as the laser light component 9b, but the paths are not similar enough for the laser light components 9a and 9c to couple to the active region of the laser diode 1. Thus, only the λ2 laser light component of the laser light is fed back to the active region of the laser diode 1 so that the diode laser operation takes place only in the longitudinal modes at wavelength λ2 and the adjoining wavelength range, and the central wavelength of the output laser light 10 is given by λ2.

By changing the angle of the partial reflective mirror 6, the central wavelength can be adjusted to a certain extent. If the angle of the partial reflective mirror 6 is adjusted such that the incident angle of the laser light component 8a is zero, the central wavelength of the output laser light 10 is given by λ1. If the angle of the partial reflective mirror 6 is adjusted such that the incident angle of the laser light component 8c is zero, the central wavelength of the output laser light 10 is given by λ3.

By adjusting the angle of the partial reflective mirror 6 within a range of approximately 1.3 mrad, the central wavelength could be adjusted within a range of approximately 10 nm. The spectral bandwidth was 0.3 nm to 0.5 nm, and the diode laser module achieved a multi longitudinal mode oscillation containing about 10 to 30 longitudinal modes with a wavelength interval corresponding to a free spectral range of 28 μm of the resonator of the laser diode 1.

Because such numerous longitudinal modes are generated, the influences of the mode hopping that can occur when the input current is varied and/or the temperature is varied on the laser power can be minimized. Therefore, an automatic power control (APC) can be performed in a stable manner for controlling the laser power at a constant level by monitoring the laser power.

The diode laser module discussed above can be constructed in a highly compact manner, and can be accommodated in a compact housing measuring 81 mm×40 mm×40 mm including the drive circuit for the laser diode 1 and the thermoelectric cooler (TEC) for controlling the temperature of the laser diode 1. This owes particularly to the fact that the output laser light 10 is parallel to the laser light emitted from the laser diode 1, and the lateral offset between the optical axes of the laser light emitted from the laser diode 1 and the output laser light 10 is only approximately 2 mm.

### Second Embodiment

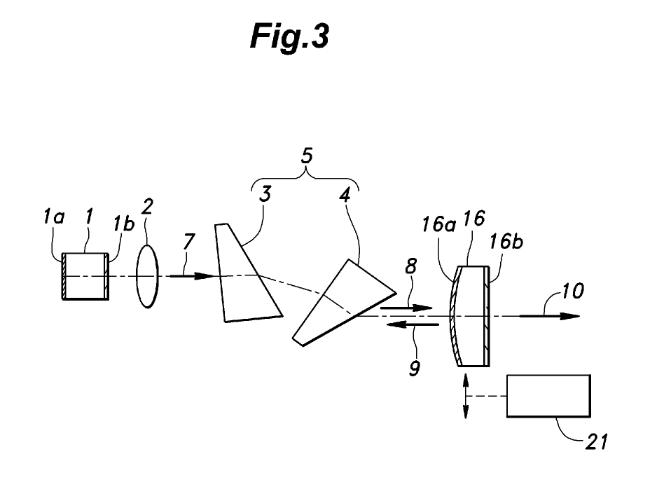

FIG. 3 shows a second embodiment of the present invention. In FIG. 3, the parts corresponding to those of the previous embodiment are denoted with like numerals without necessarily repeating the description of such parts. In this embodiment also, the laser light emitted from the laser diode 1 is collimated by the collimator lens 2, and the beam of the laser light is shaped as the laser light passes through the anamorphic prism pair 5. Furthermore, as the laser light passes through the anamorphic prism pair 5, the various wavelength components 8a, 8b and 8c of the laser light 8 are deflected in a wavelength dependent manner.

The second embodiment differs from the first embodiment illustrated in FIG. 1 in that the surface of a partial reflective mirror 16 facing the anamorphic prism pair 5 and coated with a partial reflective multi layer dielectric coating 16a is formed as a spherical surface having a radius of curvature of about 1 m. The other surface facing away from the anamorphic prism pair 5 is formed as a planar surface and coated with an anti reflective coating 16b. The surface coated with the anti reflective coating 16b is perpendicular to the optical axis of the laser light 8. The partial reflective mirror 16 is disposed in such a manner that the optical axis of the incident laser light 8 is directed to the center of the curvature of the spherical surface coated with the partial reflective multi layer dielectric coating 16a, or is directed perpendicular to a tangential plane at the point at which the laser light 8 is made incident to the partial reflective mirror 16. The partial reflective multi layer dielectric coating 16a is provided with a reflectance of about 20% for a wavelength range of the laser light 8.

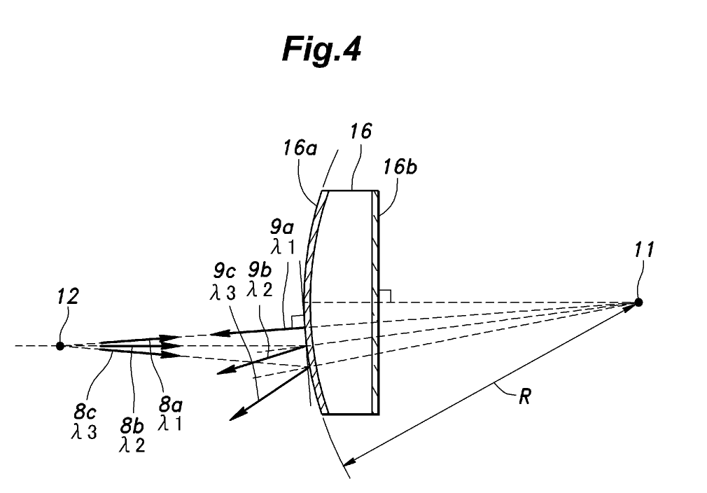

This diode laser module further comprises a sliding mechanism 21 for adjusting the position of the partial reflective mirror 16 in a direction perpendicular to the optical axis or in a vertical direction in FIGS. 3 and 4.

The working principle of the wavelength selection in the second embodiment is described in the following with reference to FIG. 4. Suppose that the laser light component 8a having a wavelength of λ1 is to be selected. The λ1 wavelength component 8a of the laser light 8 is directed to the center of curvature 11 of the curved surface of the partial reflective mirror 16. As the λ1 wavelength component 8a of the laser light 8 is made incident to the curved surface perpendicularly to the tangential plane at the incident point (zero incident angle), the laser light component reflected by this surface (namely, reflected laser light component 9a) doubles back the preceding light path, and is coupled to the active region of the laser diode 1. On the other hand, the remaining light components 8b and 8c or the λ2 and λ3 wavelength components are also reflected by the partial reflective coating 16a, but owing to the non-zero incident angles thereof, the reflected laser light components 9b and 9c follow similar paths as the laser light component 9a, but the paths are not similar enough for the laser light components 9b and 9c to couple to the active region of the laser diode 1. Thus, only the λ1 laser light component 9a of the laser light is fed back to the active region of the laser diode 1 so that the diode laser operation takes place only in the longitudinal modes at wavelength λ1 and the adjoining wavelength range, and the central wavelength of the output laser light 10 is given by λ1.

The wavelength of the output laser light 10 of this diode laser module can be varied by moving the partial reflective mirror 16 in a direction perpendicular to the optical axis of the incident laser light 8 by using the sliding mechanism 21. For instance, when the position of the partial reflective mirror 16 is adjusted such that the extension of the direction of the λ2 component 8b of the laser light 8 passes through the center of curvature 11 of the partial reflective mirror 16, the central wavelength of the output laser light 10 is given by λ2. When the position of the partial reflective mirror 16 is adjusted such that the extension of the direction of the λ3 component 8c of the laser light 8 passes through the center of curvature 11 of the partial reflective mirror 16, the central wavelength of the output laser light 10 is given by λ3.

The distance between an imaginary point 12 at which the different laser light components start dispersing and the opposing curved surface of the partial reflective mirror 16 is significantly smaller than the distance between the curved surface of the partial reflective mirror 16 and the center of curvature 11 of the curved surface or the radius of curvature R of the curved surface. Therefore, if the partial reflective mirror 16 is displaced perpendicularly to the optical axis by δ, and the wavelength dispersion angle is β, the changes in the wavelength of the laser light that couples to the active region of the laser diode 1 can be given approximately by δ/βR.

By adjusting the position of the partial reflective mirror 16 within a range of approximately 1.5 mm, the central wavelength of the laser could be varied over a range of approximately 10 nm. Similarly as in the first embodiment, the diode laser module achieved a multi longitudinal mode oscillation containing about 10 to 30 longitudinal modes, and the influences of the mode hopping that can occur when the input current is varied and/or the temperature is varied on the laser power was minimized. Also, the laser diode module was small enough to be accommodated in a housing similar to that of the first embodiment.

Although the present invention has been described in terms of preferred embodiments thereof, it is obvious to a person skilled in the art that various alterations and modifications are possible without departing from the scope of the present invention which is set forth in the appended claims.

For instance, in the foregoing embodiments, the first prism 3 and the second prism 4 were made of a same glass material and given with different apex angles so that the anamorphic prism pair 5 may be given with an appropriate wavelength dispersion property. If the two prisms 3 and 4 are made of different glass materials having different refraction indices, even when the apex angles of the two prisms are the same, similar results as the foregoing embodiments can be achieved. If desired, both the apex angles and the refractive indices of the two prisms may also be different from one another. It is also possible to invert one of the prisms 3 and 4, and still obtain similar results as the foregoing embodiments.

The contents of the original Japanese patent application on which the Paris Convention priority claim is made for the present application as well as the contents of the prior art references mentioned in this application are incorporated in this application by reference.

1. A diode laser module, comprising:
a laser diode having a laser light emitting end coated with an anti reflective coating;
a collimator lens for collimating laser light emitted from the laser diode;
an anamorphic prism pair consisting of a pair of prisms having mutually different apex angles and/or made of materials having mutually different refractive indices for shaping a beam of the laser light collimated by the collimator lens into a substantially circular cross section, wherein a deflection angle of the shaped laser light leaving the anamorphic prism pair has a wavelength dependency; and
a partial reflective mirror disposed on a side of the anamorphic prism pair away from the laser diode for reflecting a part of the shaped laser light transmitted by the anamorphic prism pair back to the laser diode via the anamorphic prism pair and the collimator lens to couple to an active region of the laser diode,
wherein a position of the partial reflective mirror is adjustable so as to adjust a wavelength of the part of the laser light reflected by the partial reflective mirror back to the laser diode.

2. The diode laser module according to claim 1, wherein laser light incident to the anamorphic prism pair and laser light emerging from the anamorphic prism pair are substantially parallel to each other.

3. The diode laser module according to claim 1, wherein the partial reflective mirror comprises a glass plate having a first surface facing the anamorphic prism pair and coated with a partial reflective coating and a second surface facing away from the anamorphic prism pair and coated with an anti reflective coating.

4. The diode laser module according to claim 3, wherein the first and second surfaces are defined by mutually parallel planes, and an angular position of the partial reflective mirror is changeable.

5. The diode laser module according to claim 3, wherein the first surface is defined by a spherical surface, and the second surface is defined by a plane, and a position of the partial reflective mirror is changeable in a direction perpendicular to laser light incident thereto.
